(19) United States
(12) Patent Application Publication
(10) Pub. No.: US 2024/0196634 A1
(43) Pub. Date: Jun. 13, 2024

(54) DETECTION DEVICE AND METHOD FOR MANUFACTURING SAME

(71) Applicant: Japan Display Inc., Tokyo (JP)

(72) Inventor: Ken OHARA, Tokyo (JP)

(21) Appl. No.: 18/531,368

(22) Filed: Dec. 6, 2023

(30) Foreign Application Priority Data
Dec. 13, 2022 (JP) 2022-198573

(51) Int. Cl. H10K 39/32; G06V 40/13

(52) U.S. Cl. CPC H10K 39/32; G06V 40/1318

(57) ABSTRACT

According to an aspect, a detection device includes: a substrate; a plurality of photodiodes, in each of which a lower electrode, a lower buffer layer, an active layer, an upper buffer layer, and an upper electrode are stacked in the order as listed, in a detection region of the substrate; and a protective film that covers the photodiodes. The protective film has a plurality of openings in the detection region.

### CROSS-REFERENCE TO RELATED APPLICATION

This application claims the benefit of priority from Japanese Patent Application No. 2022-198573 filed on Dec. 13, 2022, the entire contents of which are incorporated herein by reference.

### BACKGROUND

### 1. Technical Field

What is disclosed herein relates to a detection device and a method for manufacturing the same.

### 2. Description of the Related Art

Optical sensors capable of detecting fingerprint patterns and vascular patterns are known (for example, Japanese Patent Application Laid-open Publication No. 2009-032005). Among such optical sensors, sensors are known each including a plurality of photodiodes (organic photodiodes (OPDs)) each including an organic semiconductor material used as an active layer. As described in International Patent Application Publication No. WO/2020/188959, in each of the photodiodes, for example, a lower electrode, an electron transport layer, an active layer, a hole transport layer, and an upper electrode are stacked in this order. The electron transport layer or the hole transport layer is also called a buffer layer.

A detection device that includes the OPDs is provided with a protective film that covers the OPDs. If water enters into a detection region provided with the OPDs from the outside of the detection device, the water may be difficult to be externally discharged because the detection region is covered with the protective film.

For the foregoing reasons, there is a need for a detection device and a method for manufacturing the same that enable good external discharge of water that has entered inside.

### SUMMARY

According to an aspect, a detection device includes: a substrate; a plurality of photodiodes, in each of which a lower electrode, a lower buffer layer, an active layer, an upper buffer layer, and an upper electrode are stacked in the order as listed, in a detection region of the substrate; and a protective film that covers the photodiodes. The protective film has a plurality of openings in the detection region.

According to an aspect, a method for manufacturing a detection device includes: stacking a circuit forming layer, a photodiode, a protective film, and a resist layer on one surface of a substrate in the order as listed; exposing the resist layer from another surface side opposite to the one surface of the substrate using a non-light-transmitting pattern included in the circuit forming layer as a mask; and removing an exposed region of the resist layer that does not overlap the non-light-transmitting pattern by developing the resist layer, and removing a portion of the protective film that does not overlap the resist layer.

### BRIEF DESCRIPTION OF THE DRAWINGS

FIG. 1 is a plan view schematically illustrating a detection device according to a first embodiment;

FIG. 2 is a block diagram illustrating a configuration example of the detection device according to the first embodiment;

FIG. 3 is a circuit diagram illustrating the detection device according to the first embodiment;

FIG. 4 is a plan view schematically illustrating pixels and openings of a protective film;

FIG. 5 is a sectional view along V-V′ of FIG. 4;

FIG. 6 is an enlarged schematic configuration diagram of a sensor;

FIG. 7 is a sectional view along VII-VII′ of FIG. 6;

FIG. 8 is a plan view schematically illustrating a first groove and second grooves provided in an organic photodiode (OPD) layer of a detection device according to a second embodiment;

FIG. 9 is a sectional view along IX-IX′ of FIG. 8;

FIG. 10 is a plan view schematically illustrating the pixels and the openings of the protective film of a detection device according to a third embodiment;

FIG. 11 is an enlarged schematic configuration diagram of the sensor of the detection device according to the third embodiment;

FIG. 12 is a sectional view along XII-XII′ of FIG. 11;

FIG. 13 is an explanatory diagram for explaining a method for manufacturing the detection device according to the third embodiment;

FIG. 14 is a plan view schematically illustrating the pixels and the openings of the protective film of a detection device according to a fourth embodiment;

FIG. 15 is a sectional view along XV-XV′ of FIG. 14;

FIG. 16 is a plan view schematically illustrating the pixels and the openings of the protective film of a detection device according to a fifth embodiment;

FIG. 17 is a sectional view along XVII-XVII′ of FIG. 16;

FIG. 18 is a plan view schematically illustrating the pixels and the openings of the protective film of a detection device according to a sixth embodiment; and

FIG. 19 is a sectional view along XIX-XIX′ of FIG. 16.

### DETAILED DESCRIPTION

The following describes modes (embodiments) for carrying out the present disclosure in detail with reference to the drawings. The present disclosure is not limited to the description of the embodiments given below. Components described below include those easily conceivable by those skilled in the art or those substantially identical thereto. In addition, the components described below can be combined as appropriate. What is disclosed herein is merely an example, and the present disclosure naturally encompasses appropriate modifications easily conceivable by those skilled in the art while maintaining the gist of the present disclosure. To further clarify the description, the drawings may schematically illustrate, for example, widths, thicknesses, and shapes of various parts as compared with actual aspects thereof. However, they are merely examples, and interpretation of the present disclosure is not limited thereto. The same component as that described with reference to an already mentioned drawing is denoted by the same reference numeral through the present disclosure and the drawings, and detailed description thereof may not be repeated where appropriate.

In the present specification and claims, in expressing an aspect of disposing another structure on or above a certain structure, a case of simply expressing “on” includes both a case of disposing the other structure immediately on the certain structure so as to contact the certain structure and a case of disposing the other structure above the certain structure with still another structure interposed therebetween, unless otherwise specified.

### First Embodiment

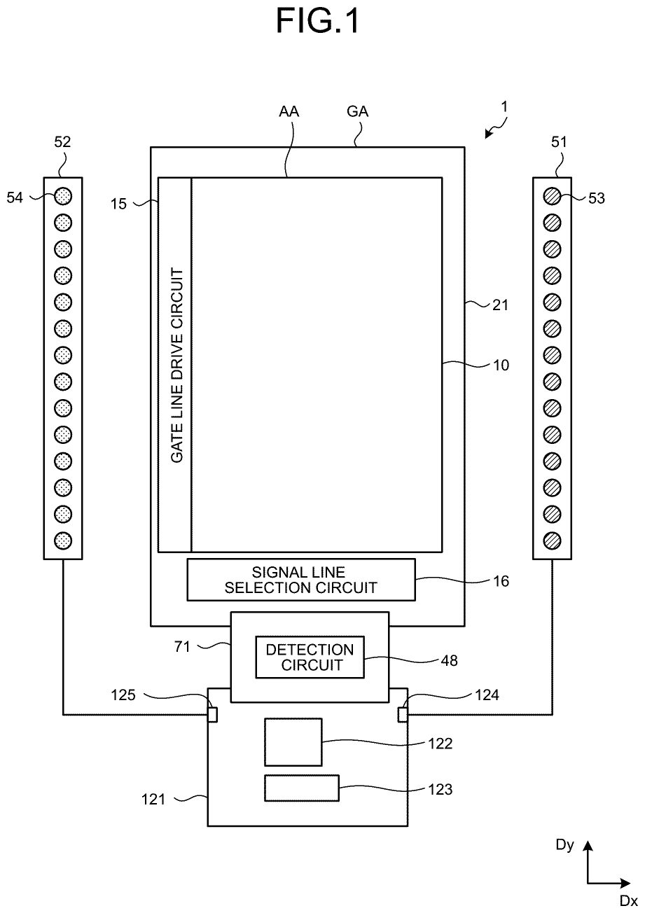

FIG. 1 is a plan view schematically illustrating a detection device according to a first embodiment. As illustrated in FIG. 1, a detection device 1 includes a sensor base member 21 (substrate), a sensor 10, a gate line drive circuit 15, a signal line selection circuit 16, a detection circuit 48, a control circuit 122, a power supply circuit 123, a first light source base member 51, a second light source base member 52, and light sources 53 and 54. The first light source base member 51 is provided with a plurality of the light sources 53. The second light source base member 52 is provided with a plurality of the light sources 54.

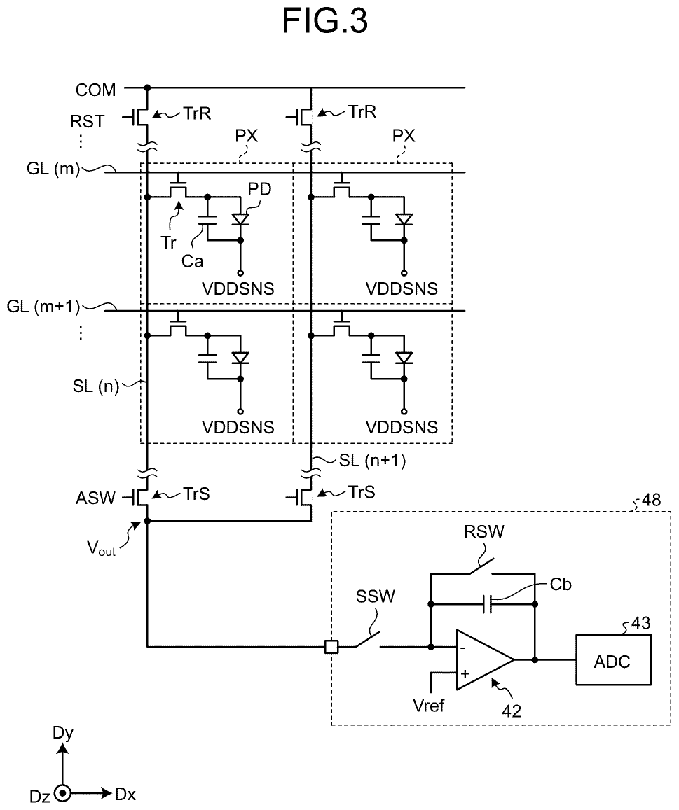

The sensor base member 21 is electrically coupled to a control substrate 121 through a wiring substrate 71. The wiring substrate 71 is, for example, a flexible printed circuit board or a rigid circuit board. The wiring substrate 71 is provided with the detection circuit 48. The control substrate 121 is provided with the control circuit 122 and the power supply circuit 123. The control circuit 122 is, for example, a field-programmable gate array (FPGA). The control circuit 122 supplies control signals to the sensor 10, the gate line drive circuit 15, and the signal line selection circuit 16 to control a detection operation of the sensor 10. The control circuit 122 supplies control signals to the light sources 53 and 54 to control lighting and non-lighting of the light sources 53 and 54. The power supply circuit 123 supplies voltage signals including, for example, a sensor power supply signal (sensor power supply voltage) VDDSNS (refer to FIG. 3) to the sensor 10, the gate line drive circuit 15, and the signal line selection circuit 16. The power supply circuit 123 supplies a power supply voltage to the light sources 53 and 54.

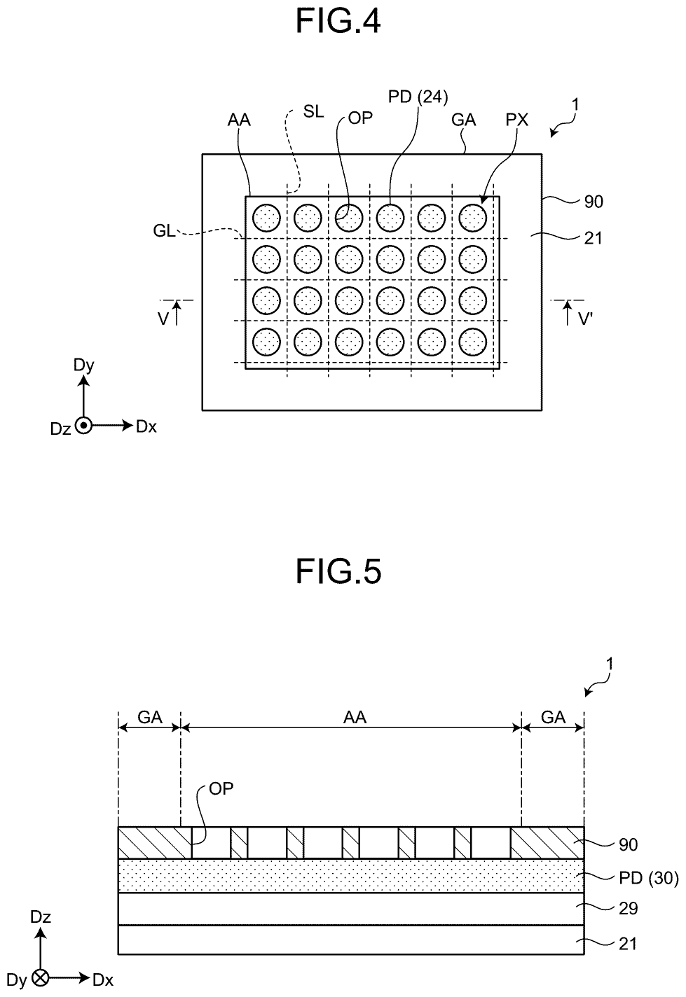

The sensor base member 21 has a detection region AA and a peripheral region GA. The detection region AA is a region provided with a plurality of photodiodes PD (refer to FIG. 4) included in the sensor 10. The peripheral region GA is a region between the outer perimeter of the detection region AA and the outer edge of the sensor base member 21 and is a region not provided with the photodiodes PD.

The gate line drive circuit 15 and the signal line selection circuit 16 are provided in the peripheral region GA. Specifically, the gate line drive circuit 15 is provided in a region extending along a second direction Dy in the peripheral region GA. The signal line selection circuit 16 is provided in a region extending along a first direction Dx in the peripheral region GA, and is provided between the sensor 10 and the detection circuit 48.

In the following description, the first direction Dx is one direction in a plane parallel to the sensor base member 21. The second direction Dy is one direction in the plane parallel to the sensor base member 21 and is a direction orthogonal to the first direction Dx. The second direction Dy may non-orthogonally intersect the first direction Dx. A third direction Dz is a direction orthogonal to the first direction Dx and the second direction Dy, and is a direction normal to the sensor base member 21. The term “plan view” refers to a positional relation when viewed from a direction orthogonal to the sensor base member 21.

The light sources 53 are provided on the first light source base member 51, and arranged along the second direction Dy. The light sources 54 are provided on the second light source base member 52, and arranged along the second direction Dy. The first light source base member 51 and the second light source base member 52 are electrically coupled, through respective terminals 124 and 125 provided on the control substrate 121, to the control circuit 122 and the power supply circuit 123.

For example, inorganic light-emitting diodes (LEDs) or organic electroluminescent (EL) diodes (organic light-emitting diodes (OLEDs)) are used as the light sources 53 and 54. The light sources 53 and 54 emit light having wavelengths different from each other.

First light emitted from the light sources 53 is mainly reflected on a surface of an object to be detected, such as a finger, and is incident on the sensor 10. As a result, the sensor 10 can detect a fingerprint by detecting a shape of asperities on the surface of the finger or the like. Second light emitted from the light sources 54 is mainly reflected in the finger or the like, or transmitted through the finger or the like, and is incident on the sensor 10. As a result, the sensor 10 can detect information on a living body in the finger or the like. Examples of the information on the living body include pulse waves, pulsation, and a vascular image of the finger or a palm. That is, the detection device 1 may be configured as a fingerprint detection device to detect a fingerprint or a vein detection device to detect a vascular pattern of, for example, veins.

The arrangement of the light sources 53 and 54 illustrated in FIG. 1 is merely an example, and can be changed as appropriate. The detection device 1 is provided with a plurality of types of the light sources 53 and 54 as light sources. However, the light sources are not limited thereto, but may be of one type. For example, the light sources 53 and 54 may be arranged on each of the first light source base member 51 and the second light source base member 52. The light sources 53 and 54 may be provided on one light source base member, or three or more light source base members. Alternatively, only at least one light source needs to be disposed.

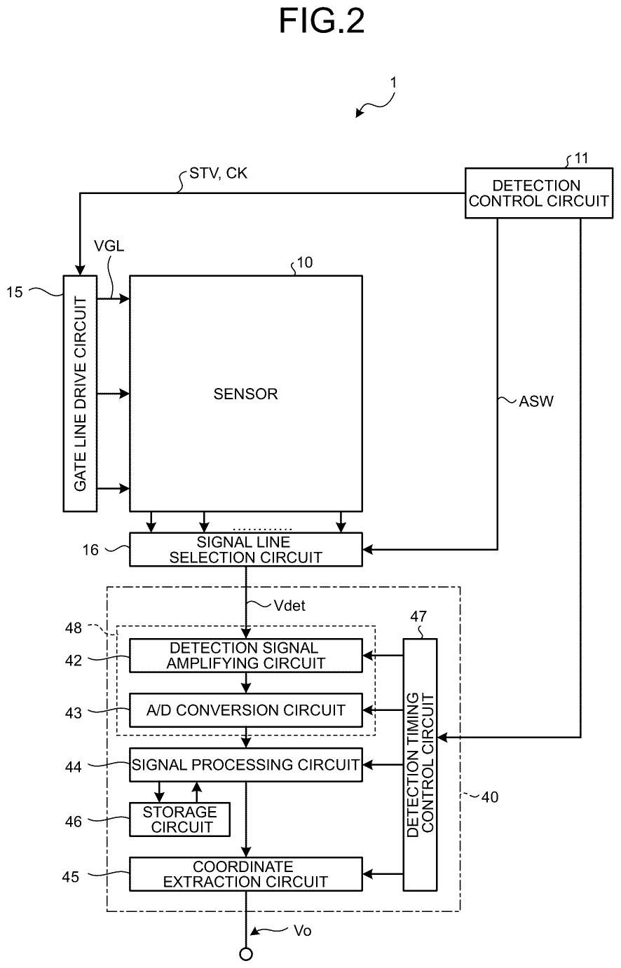

FIG. 2 is a block diagram illustrating a configuration example of the detection device according to the first embodiment. As illustrated in FIG. 2, the detection device 1 further includes a detection control circuit 11 and a detector (detection signal processing circuit) 40. The control circuit 122 includes one, some, or all functions of the detection control circuit 11. The control circuit 122 also includes one, some, or all functions of the detector 40 other than those of the detection circuit 48.

The sensor 10 includes the photodiodes PD. Each of the photodiodes PD included in the sensor 10 outputs an electrical signal corresponding to light received by the photodiode PD as a detection signal Vdet to the signal line selection circuit 16. The sensor 10 perform the detection in response to a gate drive signal VGL supplied from the gate line drive circuit 15.

The detection control circuit 11 is a circuit that supplies respective control signals to the gate line drive circuit 15, the signal line selection circuit 16, and the detector 40 to control operations of these components. The detection control circuit 11 supplies various control signals including, for example, a start signal STV and a clock signal CK to the gate line drive circuit 15. The detection control circuit 11 also supplies various control signals including, for example, a selection signal ASW to the signal line selection circuit 16. The detection control circuit 11 also supplies various control signals to the light sources 53 and 54 to control the lighting and non-lighting of the respective light sources 53 and 54.

The gate line drive circuit 15 is a circuit that drives a plurality of gate lines GL (refer to FIG. 3) based on the various control signals. The gate line drive circuit 15 sequentially or simultaneously selects the gate lines GL, and supplies the gate drive signals VGL to the selected gate lines GL. By this operation, the gate line drive circuit 15 selects the photodiodes PD coupled to the gate lines GL.

The signal line selection circuit 16 is a switch circuit that sequentially or simultaneously selects a plurality of signal lines SL (refer to FIG. 3). The signal line selection circuit 16 is, for example, a multiplexer. The signal line selection circuit 16 couples the selected signal lines SL to the detection circuit 48 based on the selection signal ASW supplied from the detection control circuit 11. By this operation, the signal line selection circuit 16 outputs the detection signals Vdet of the photodiodes PD to the detector 40.

The detector 40 includes the detection circuit 48, a signal processing circuit 44, a coordinate extraction circuit 45, a storage circuit 46, and a detection timing control circuit 47. The detection timing control circuit 47 performs control to cause the detection circuit 48, the signal processing circuit 44, and the coordinate extraction circuit 45 to operate in synchronization with one another based on a control signal supplied from the detection control circuit 11.

The detection circuit 48 is, for example, an analog front-end (AFE) circuit. The detection circuit 48 is a signal processing circuit having functions of at least a detection signal amplifying circuit 42 and an analog-to-digital (A/D) conversion circuit 43. The detection signal amplifying circuit 42 amplifies the detection signal Vdet. The A/D conversion circuit 43 converts an analog signal output from the detection signal amplifying circuit 42 into a digital signal.

The signal processing circuit 44 is a logic circuit that detects a predetermined physical quantity received by the sensor 10 based on output signals of the detection circuit 48. The signal processing circuit 44 can detect the asperities on the surface of the finger or the palm based on the signals from the detection circuit 48 when the finger is in contact with or in proximity to a detection surface. The signal processing circuit 44 can detect the information on the living body based on the signals from the detection circuit 48. Examples of the information on the living body include the vascular image, the pulse waves, the pulsation, and a blood oxygen level of the finger or the palm.

The storage circuit 46 temporarily stores therein signals calculated by the signal processing circuit 44. The storage circuit 46 may be, for example, a random-access memory (RAM) or a register circuit.

The coordinate extraction circuit 45 is a logic circuit that obtains detected coordinates of the asperities on the surface of the finger or the like when the contact or proximity of the finger is detected by the signal processing circuit 44. The coordinate extraction circuit 45 is the logic circuit that also obtains detected coordinates of blood vessels in the finger or the palm. The coordinate extraction circuit 45 combines the detection signals Vdet output from the photodiodes PD of the sensor 10 to generate two-dimensional information indicating the shape of the asperities on the surface of the finger or the like and two-dimensional information indicating the shape of the blood vessels in the finger or the palm. The coordinate extraction circuit 45 may output the detection signals Vdet as sensor output voltages Vo instead of calculating the detected coordinates.

FIG. 3 is a circuit diagram illustrating the detection device according to the first embodiment. FIG. 3 also illustrates a circuit configuration of the detection circuit 48. As illustrated in FIG. 3, a sensor pixel PX includes the photodiode PD, a capacitive element Ca, and a drive transistor Tr. The capacitive element Ca is capacitance (sensor capacitance) generated in the photodiode PD and is equivalently coupled in parallel to the photodiode PD.

FIG. 3 illustrates two gate lines GL(m) and GL(m+1) arranged in the second direction Dy among the gate lines GL. FIG. 3 also illustrates two signal lines SL(n) and SL(n+1) arranged in the first direction Dx among the signal lines SL. The sensor pixel PX is a region surrounded by the gate lines GL and the signal lines SL.

The drive transistors Tr are provided correspondingly to the photodiodes PD. Each of the drive transistors Tr is formed of a thin-film transistor, and in this example, formed of an n-channel metal oxide semiconductor (MOS) thin-film transistor (TFT).

Each of the gate lines GL is coupled to the gates of the drive transistors Tr arranged in the first direction Dx. Each of the signal lines SL is coupled to either the sources or the drains of the drive transistors Tr arranged in the second direction Dy. The others of the sources and the drains of the drive transistors Tr are coupled to the anodes of the photodiodes PD and the capacitive elements Ca.

The cathode of the photodiode PD is supplied with the sensor power supply signal VDDSNS from the power supply circuit 123 (refer to FIG. 1). The signal line SL and the capacitive element Ca are supplied with a sensor reference voltage COM that serves as an initial potential of the signal line SL and the capacitive element Ca from the power supply circuit 123 through a reset transistor TrR.

When the sensor pixel PX is irradiated with light in an exposure period, a current corresponding to the amount of the light flows through the photodiode PD. As a result, an electric charge is stored in the capacitive element Ca. After the drive transistor Tr is turned on in a read period, a current corresponding to the electric charge stored in the capacitive element Ca flows through the signal line SL. The signal line SL is coupled to the detection circuit 48 through an output transistor TrS of the signal line selection circuit 16. Thus, the detection device 1 can detect a signal corresponding to the amount of the light received by the photodiode PD for each of the sensor pixels PX.

During the read period, a switch SSW is turned on to couple the detection circuit 48 to the signal line SL. The detection signal amplifying circuit 42 of the detection circuit 48 converts a current or an electric charge supplied from the signal line SL into a voltage corresponding thereto. A reference potential (Vref) having a fixed potential is supplied to a non-inverting input portion (+) of the detection signal amplifying circuit 42, and the signal lines SL are coupled to an inverting input portion (−) of the detection signal amplifying circuit 42. In the present embodiment, the same signal as the sensor reference voltage COM is supplied as the reference potential (Vref) voltage. The control circuit 122 (refer to FIG. 1) calculates, as each of the sensor output voltages Vo, the difference between the detection signal Vdet when light irradiates the optical sensor PD and the detection signal Vdet when the optical sensor PD is not irradiated by light. The detection signal amplifying circuit 42 includes a capacitive element Cb and a reset switch RSW. During a reset period, the reset switch RSW is turned on to reset the electric charge of the capacitive element Cb.

The drive transistor Tr is not limited to being formed of the n-channel TFT, but may be formed of a p-channel TFT. The pixel circuit of the sensor pixel PX illustrated in FIG. 3 is merely exemplary. The sensor pixel PX may be provided with a plurality of transistors corresponding to one photodiode PD.

FIG. 4 is a plan view schematically illustrating pixels and openings of a protective film. In FIG. 4, for ease of viewing, a plurality of openings OP provided in a protective film 90 are illustrated with shading. As illustrated in FIG. 4, the sensor pixels PX are arranged in a matrix having a row-column configuration in the detection region AA of the sensor base member 21 and each include the photodiode PD. In FIG. 4, the sensor pixels PX are arranged in four rows and six columns. FIG. 4, however, illustrates the arrangement of the sensor pixels PX in a simplified manner for ease of understanding. The detection device 1 may include a larger number of the sensor pixels PX in five or more rows and seven or more columns, depending on the type of the object to be detected and the resolution of the detection.

The gate lines GL each extend in the first direction Dx and are arranged with gaps interposed therebetween in the second direction Dy. The signal lines SL each extend in the second direction Dy and are arranged with gaps interposed therebetween in the first direction Dx. The sensor electrodes PX (photodiodes PD) are each provided in a region surrounded by two of the gate lines GL and two of the signal lines SL.

The protective film 90 is provided so as to cover the sensor electrodes PX (photodiodes PD). The protective film 90 is provided in the detection region AA and the peripheral region GA of the sensor base member 21. The protective film 90 has the openings OP in the detection region AA. The openings OP are provided in regions overlapping the respective sensor pixels PX and arranged in a matrix having a row-column configuration in the detection region AA. In other words, each of the openings OP is provided in the region surrounded by two of the gate lines GL and two of the signal lines SL.

The openings OP are circular in plan view. The openings OP have a substantially equal area (size) or diameter. An upper electrode 24 of the photodiode PD is disposed at the bottom of the opening OP.

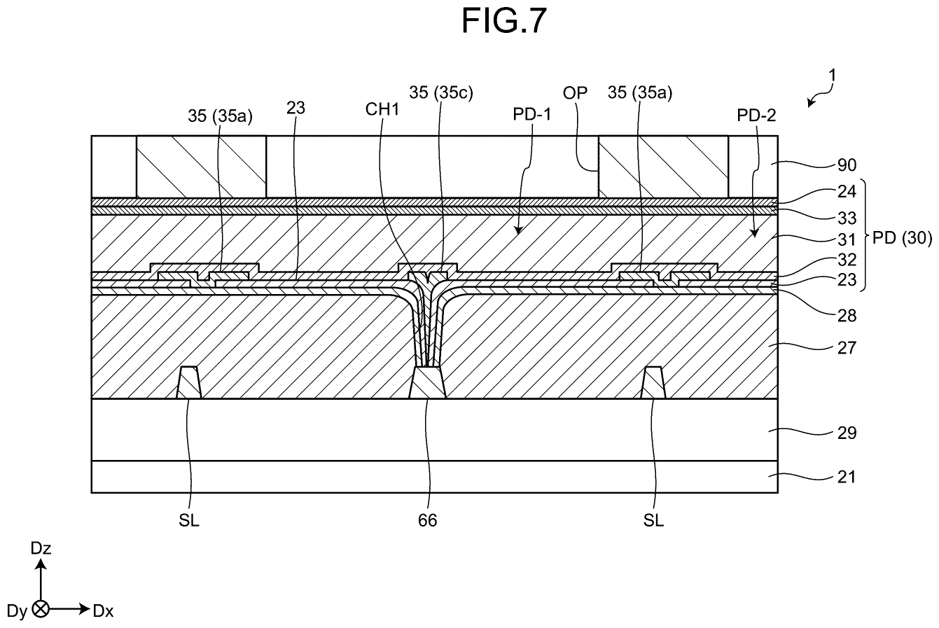

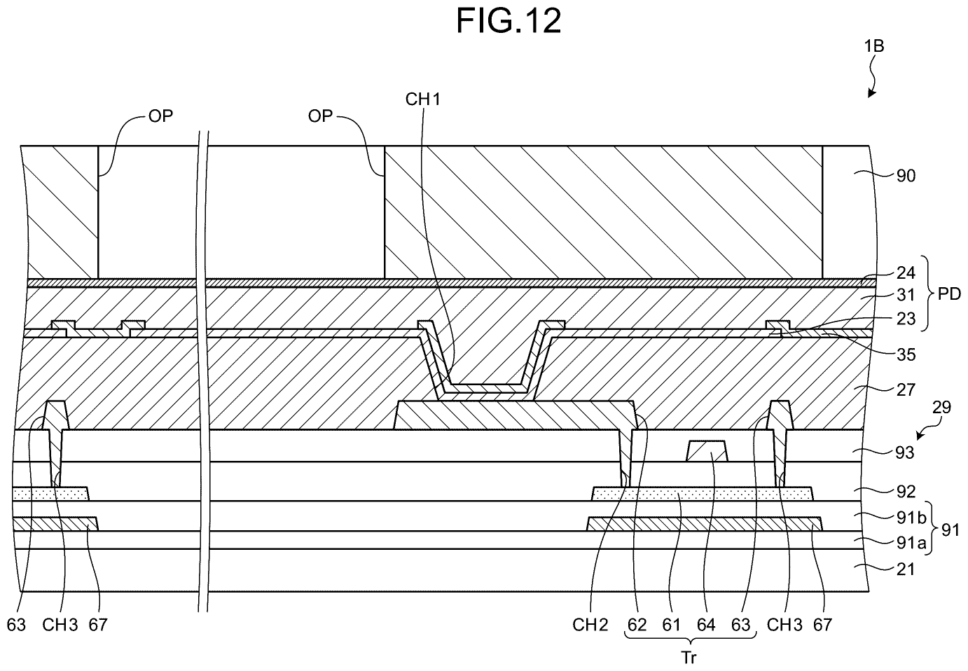

FIG. 5 is a sectional view along V-V′ of FIG. 4. FIG. 5 illustrates a configuration of each layer in a simplified manner for ease of understanding. A detailed layered configuration of the photodiodes PD will be described later with reference to FIG. 7. A detailed layered configuration of a circuit forming layer 29 will be described later with reference to FIG. 12.

In the following description, a direction from the sensor base member 21 toward the protective film 90 in a direction orthogonal to a surface of the sensor base member 21 is referred to as “upper side” or simply “above”. A direction from the protective film 90 toward the sensor base member 21 is referred to as “lower side” or simply “below”.

As illustrated in FIG. 5, in the detection device 1, the circuit forming layer 29, the photodiodes PD, and the protective film 90 are stacked on the sensor base member 21 in the order as listed. The circuit forming layer 29 is a layer that is provided on the sensor base member 21, and in which various transistors, such as the drive transistors Tr, and various types of wiring, such as the gate lines GL and the signal lines SL, illustrated in FIG. 3 are formed.

The photodiodes PD are provided on the circuit forming layer 29. An organic photodiode (OPD) layer 30 (lower electrodes 23, a lower buffer layer 32, an active layer 31, an upper buffer layer 33, and the upper electrode 24 (refer to FIG. 7)) forming the photodiodes PD is provided continuously over the detection region AA and peripheral region GA. The OPD layer 30 provided in the peripheral region GA is configured not to serve as an optical sensor.

The protective film 90 is provided on the photodiodes PD (OPD layer 30). An inorganic film, such as a silicon nitride film or an aluminum oxide film, or a resin film, such as an acrylic film, is used as the protective film 90. The protective film 90 is not limited to being a single layer, but may be a multilayered film having two or more layers obtained by combining the inorganic insulating film with the organic insulating film (resin film) mentioned above. By forming the protective film 90 with a multilayer film, the thickness of the protective film 90 can be ensured, and the strength on the upper surface side of the photodiode PD can be obtained. The openings OP are provided so as to penetrate from the upper surface to the lower surface of the protective film 90. In the present embodiment, the openings OP are provided on the photodiodes PD in a region overlapping the detection region AA and not provided on the OPD layer 30 in a region overlapping the peripheral region GA.

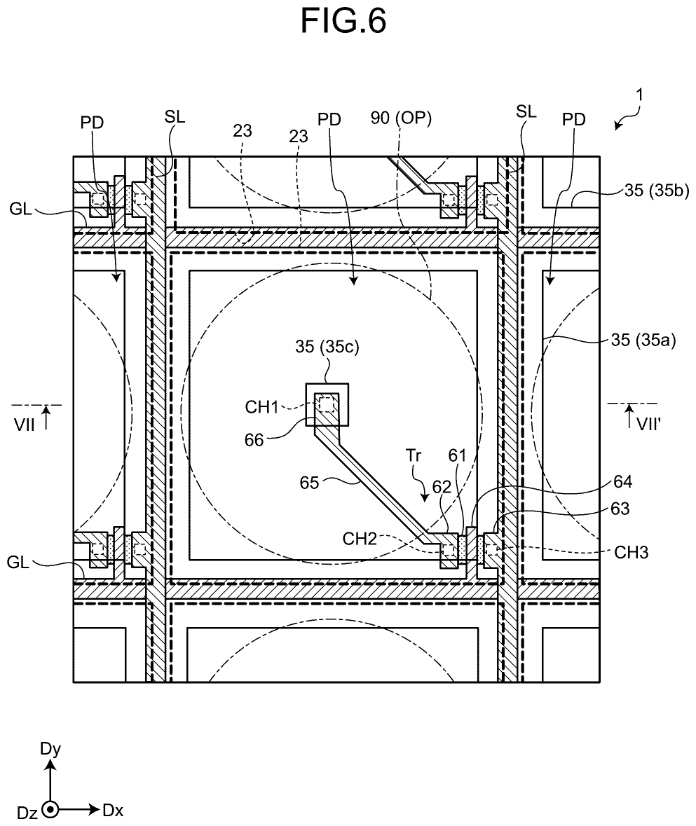

The following describes a detailed configuration of the photodiodes PD and the protective film 90. FIG. 6 is an enlarged schematic configuration diagram of the sensor. For ease of viewing, FIG. 6 illustrates the openings OP of the protective film 90 with dash-dot lines.

As illustrated in FIG. 6, the detection device 1 includes the photodiodes PD provided to the sensor base member 21, and an insulating film 35. The lower electrodes 23 of the photodiodes PD are provided in a matrix having a row-column configuration corresponding to the photodiodes PD above the sensor base member 21. In the example illustrated in FIG. 6, the right and bottom sides of each of the lower electrodes 23 overlap part of the signal line SL and part gate line GL, respectively. The left and top sides of the lower electrode 23 are arranged with gaps from the signal line SL and gate line GL, respectively. This configuration can increase the area (size) of the lower electrode 23 in the region surrounded by two of the gate lines GL and two of the signal lines SL, and thus can improve the detection sensitivity of the photodiode PD.

The drive transistor Tr is provided in a region overlapping the lower electrode 23 of photodiode PD. Specifically, the drive transistor Tr includes a semiconductor layer 61, a source electrode 62, a drain electrode 63, and a gate electrode 64. The semiconductor layer 61 extends along the gate line GL and is provided so as to intersect the gate electrode 64 in plan view. The gate electrode 64 is coupled to the gate line GL and extends in a direction (second direction Dy) orthogonal to the gate line GL.

One end side of the semiconductor layer 61 is coupled to the source electrode 62 through a contact hole CH2. The source electrode 62 is coupled to coupling wiring 65 and a coupling pad 66 and drawn to a central portion of the photodiode PD (lower electrode 23). The lower electrode 23 is coupled to the coupling pad 66 at the central portion through a contact hole CH1. Such a configuration electrically couples the source electrode 62 of the drive transistor Tr to the photodiode PD. The other end side of the semiconductor layer 61 is coupled to the drain electrode 63 through a contact hole CH3. The drain electrode 63 is coupled to the signal line SL.

The insulating film 35 is provided between the lower electrodes 23 adjacent in the first direction Dx and the second direction Dy and is provided so as to cover the peripheries of the lower electrodes 23. In more detail, the insulating film 35 is formed in a grid pattern in which first extending portions 35a intersect second extending portions 35b. The first extending portions 35a extend in the second direction Dy. The first extending portions 35a are provided so as to overlap the signal lines SL and extend along the signal lines SL. The second extending portions 35b extend in the first direction Dx. The second extending portions 35b are provided so as to overlap the gate lines GL and extend along the gate lines GL.

An island portion 35c is provided separately from the first extending portions 35a and the second extending portions 35b and is provided in a region overlapping the contact hole CH1 at the central portion of the photodiode PD (lower electrode 23).

For example, the shapes and the arrangement pitches of the lower electrodes 23 and the insulating film 35 illustrated in FIG. 6 are only exemplary, and can be changed as appropriate according to the characteristics and the detection accuracy required for the detection device 1.

FIG. 7 is a sectional view along VII-VII′ of FIG. 6. As illustrated in FIG. 7, in the detection device 1, the circuit forming layer 29, an insulating film 27, the photodiode PD, and the protective film 90 are stacked on the sensor base member 21 in the order as listed. The sensor base member 21 is an insulating substrate and is made using, for example, a glass substrate of, for example, quartz or alkali-free glass. The sensor base member 21 is not limited to having a flat plate shape but may have a curved surface. In this case, the sensor base member 21 may be a film-like resin material.

The circuit forming layer 29 is provided on the sensor base member 21. FIG. 5 illustrates the signal lines SL coupled to the drive transistors Tr among the drive transistors Tr and the various types of wiring provided in the circuit forming layer 29. The insulating film 27 is provided on the circuit forming layer 29 including the drive transistors Tr so as to cover the signal lines SL. The insulating film 27 is an organic planarizing film formed of an organic insulating material.

An insulating film 28 is provided on the insulating film 27. The insulating film 28 is a barrier film formed of an inorganic insulating material such as a silicon nitride film (SiN).

The photodiode PD and the insulating film 35 are provided on the insulating film 28. In more detail, the photodiode PD includes the lower electrode 23, the lower buffer layer 32, the active layer 31, the upper buffer layer 33, and the upper electrode 24. The photodiode PD is configured such that the lower electrode 23, the lower buffer layer 32 (hole transport layer), the active layer 31, the upper buffer layer 33 (electron transport layer), and the upper electrode 24 are stacked in the order as listed, in the direction orthogonal to the sensor base member 21. The photodiode PD of the present embodiment is an organic photodiode (OPD) made using an organic semiconductor as the active layer 31.

The OPD layer 30 described above is a multilayered body in which the lower electrodes 23, the lower buffer layer 32, the active layer 31, the upper buffer layer 33, and the upper electrode 24 that form the photodiodes PD are stacked. Since the OPD layer 30 provided in the peripheral region GA (refer to FIG. 5) does not serve as the photodiode PD, one or more of the lower electrode 23, the lower buffer layer 32, the active layer 31, the upper buffer layer 33, and the upper electrode 24 may be omitted. The OPD layer 30 need not be provided in the entire peripheral region GA, and part of the peripheral region GA need not be provided with the OPD layer 30.

The lower electrode 23 is an anode electrode of the photodiode PD and is formed of, for example, a light-transmitting conductive material such as indium tin oxide (ITO). The lower electrodes 23 are separated from each other so as to correspond to the photodiodes PD. The lower buffer layer 32, the active layer 31, the upper buffer layer 33, and the upper electrode 24 are provided continuously over the photodiodes PD. Specifically, the lower buffer layer 32, the active layer 31, the upper buffer layer 33, and the upper electrode 24 are provided so as to overlap an adjacent pair of the lower electrode 23 of a photodiode PD-1 and the lower electrode 23 of a photodiode PD-2, and overlap also the insulating film 35 between the photodiodes PD-1 and PD-2.

The insulating film 35 (first extending portion 35a) is provided above the insulating film 28 between the adjacent lower electrodes 23, and covers the peripheries of the lower electrodes 23. In the present embodiment, the insulating film 35 is formed of an inorganic insulating material, such as a silicon nitride film (SiN) or a silicon oxide film (SiO₂). The insulating film 35 (first extending portion 35a) insulates the lower electrodes 23 of the adjacent photodiodes PD from each other.

The contact hole CH1 is provided so as to penetrate the insulating film 27 in the thickness direction thereof (third direction Dz) at the central portion of the lower electrode 23. The lower electrode 23 is coupled to the coupling pad 66 at the bottom of the contact hole CH1. The island portion 35c is provided so as to cover the contact hole CH1 and covers the lower electrode 23 in the contact hole CH1. The island portion 35c overlaps the coupling pad 66 in plan view. With this configuration, even if a step break occurs in the lower buffer layer 32 (hole transport layer) in the contact hole CH1, a short circuit between the active layer 31 and the lower electrode 23 can be restrained from occurring because the island portion 35c is provided.

The active layer 31 changes in characteristics (for example, voltage-current characteristics and resistance value) according to light emitted thereto. An organic material is used as a material of the active layer 31. Specifically, the active layer 31 has a bulk heterostructure containing a mixture of a p-type organic semiconductor and an n-type fullerene derivative (PCBM) that is an n-type organic semiconductor. As the active layer 31, low-molecular-weight organic materials can be used including, for example, fullerene (C₆₀), phenyl-C₆₁-butyric acid methyl ester (PCBM), copper phthalocyanine (CuPc), fluorinated copper phthalocyanine (F₁₆CuPc), 5,6,11,12-tetraphenyltetracene (rubrene), and perylene diimide (PDI) (derivative of perylene).

The active layer 31 can be formed by a vapor deposition process (dry process) using the low-molecular-weight organic materials listed above. In this case, the active layer 31 may be, for example, a multilayered film of CuPc and F₁₆CuPc, or a multilayered film of rubrene and C₆₀. The active layer 31 can also be formed by a coating process (wet process). In this case, the active layer 31 is made using a material obtained by combining the above-listed low-molecular-weight organic materials with a high-molecular-weight organic material. As the high-molecular-weight organic material, for example, poly(3-hexylthiophene) (P3HT) and F8-alt-benzothiadiazole (F8BT) can be used. The active layer 31 can be a film made of a mixture of P3HT and PCBM, or a film made of a mixture of F8BT and PDI.

The lower buffer layer 32 is a hole transport layer, and the upper buffer layer 33 is an electron transport layer. The lower buffer layer 32 and the upper buffer layer 33 are provided to facilitate holes and electrons generated in the active layer 31 to reach the lower electrode 23 or the upper electrode 24. The lower buffer layer 32 (hole transport layer) is in direct contact with the top of the lower electrode 23 and is also provided on the insulating film 35 between the adjacent lower electrodes 23. The active layer 31 is in direct contact with the top of the lower buffer layer 32. The material of the hole transport layer is an oxide metal layer. For example, tungsten oxide (WO₃) or molybdenum oxide is used as the oxide metal layer.

The upper buffer layer 33 (electron transport layer) is in direct contact with the top of the active layer 31, and the upper electrode 24 is in direct contact with the top of the upper buffer layer 33. Polyethylenimine ethoxylated (PEIE) is used as a material of the electron transport layer.

The materials and the manufacturing methods of the lower buffer layer 32, the active layer 31, and the upper buffer layer 33 are merely exemplary, and other materials and manufacturing methods may be used. For example, each of the lower buffer layer 32 and the upper buffer layer 33 is not limited to a single-layer film but may be formed as a multilayered film that includes an electron block layer and a hole block layer. The lower buffer layer 32 may be the electron transport layer; the upper buffer layer 33 the hole transport layer; the lower electrode 23 may be the cathode electrode; and the upper electrode 24 may be the anode electrode.

The upper electrode 24 is provided on the upper buffer layer 33. The upper electrode 24 is the cathode electrode of the photodiode PD and is continuously formed over the entire detection region AA. In other words, the upper electrode 24 is continuously provided in the upper side layer of the photodiodes PD. The upper electrode 24 faces the lower electrodes 23 with the lower buffer layer 32, the active layer 31, and the upper buffer layer 33 interposed therebetween. The upper electrode 24 is formed of, for example, a light-transmitting conductive material such as ITO or indium zinc oxide (IZO). The upper electrode 24 may be a multilayered film of a plurality of light-transmitting conductive materials.

The protective film 90 is provided so as to cover the photodiodes PD. Specifically, the protective film 90 is provided on the upper electrode 24. Each of the openings OP of the protective film 90 is provided in a region overlapping the OPD layer 30 (the lower electrode 23, the lower buffer layer 32, the active layer 31, the upper buffer layer 33, and the upper electrode 24) forming the photodiode PD. In other words, the protective film 90 (portion where the openings OP are not provided) is provided at least in a region overlapping the signal lines SL and the gate lines GL (refer to FIG. 6).

In the detection device 1 of the present embodiment, the openings OP of the protective film 90 are provided in regions overlapping the photodiodes PD. With this configuration, even if water enters inside the photodiodes PD in the detection region AA from outside, for example, through the OPD layer 30 in the peripheral region GA from an end of the outer edge of the sensor base member 21, the water is discharged outward through the openings OP of the protective film 90. Consequently, the detection device 1 can well discharge outward the water that has entered inside. Thus, the detection device 1 can reduce the amount of a reduction in detection sensitivity that would be caused by the penetration and accumulation of water into the OPD layer 30 of the photodiodes PD.

The shape, the positions, the number, and the like of the openings OP illustrated in FIGS. 4 to 7 are merely exemplary, and can be changed as appropriate depending on the arrangement or the like of the photodiodes PD. The configuration of the photodiode PD illustrated in FIGS. 6 and 7 is merely exemplary, and can be changed as appropriate. For example, the upper electrode 24 may be the anode electrode of the photodiode PD, and the lower electrode 23 may be the cathode electrode of the photodiode PD.

### Second Embodiment

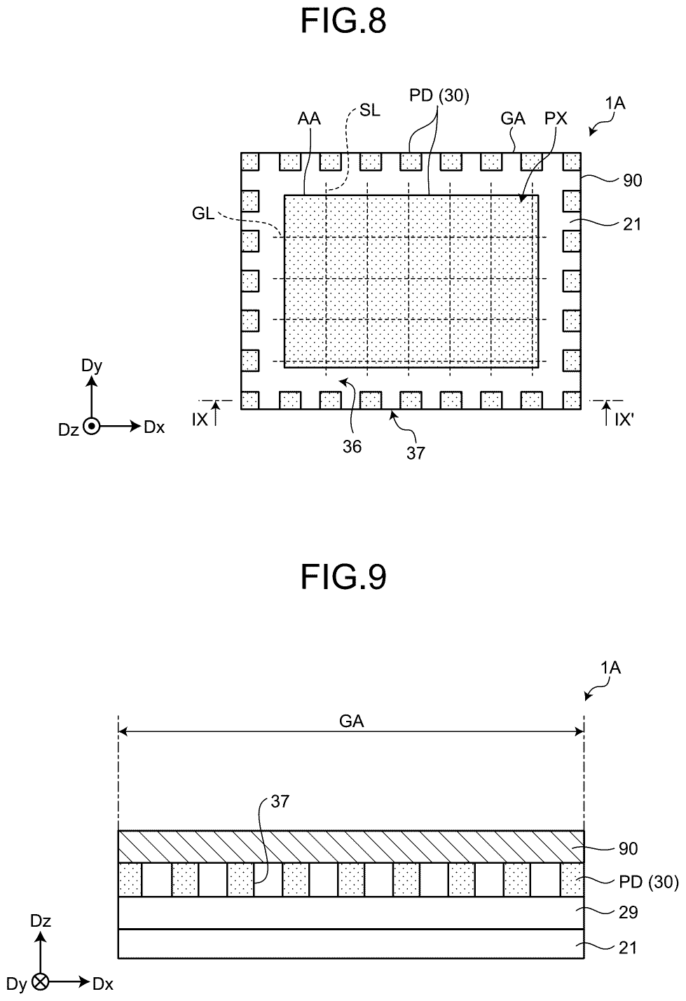

FIG. 8 is a plan view schematically illustrating a first groove and second grooves provided in the OPD layer of a detection device according to a second embodiment. FIG. 9 is a sectional view along IX-IX′ of FIG. 8. In FIG. 8, for ease of viewing, the OPD layer 30 is illustrated with shading. In the following description, the same components as those described in the embodiment described above are denoted by the same reference numerals, and the description thereof will not be repeated.

As illustrated in FIGS. 8 and 9, in a detection device 1A according to the second embodiment, the OPD layer 30 forming the photodiodes PD is provided in the detection region AA of the sensor base member 21 and in the peripheral region GA adjacent to the detection region AA. The OPD layer 30 is provided continuously over the entire surface of the detection region AA. In the peripheral region GA, the OPD layer 30 has a first groove 36 and second grooves 37.

As illustrated in FIG. 8, the first groove 36 extends along the outer edge of the detection region AA and is provided in a frame shape corresponding to the external shape of the detection region AA. In the second embodiment, the detection region AA has a quadrilateral shape, and the first groove 36 is provided also in a quadrilateral shape.

The second grooves 37 are provided between the first groove 36 and the outer edge of the peripheral region GA. More specifically, the second grooves 37 extend in directions that intersect the sides of the detection region AA. One end of each of the second grooves 37 on the detection region AA side is coupled to the first groove 36. The other end of the second groove 37 opposite the detection region AA is open on the outer edge side of the peripheral region GA. In other words, a plurality of the OPD layers 30 located at the outer edge of the peripheral region GA are separated from the OPD layer 30 in the detection region AA by the first groove 36. The OPD layers 30 separated by the second grooves 37 are arranged along the outer edge of the peripheral region GA.

As illustrated in FIG. 9, the second grooves 37 are arranged in the first direction Dx in portions of the peripheral region GA that extend in the first direction Dx. The first groove 36 (not illustrated in FIG. 9) and the second grooves 37 are each provided through the OPD layers 30 in the third direction Dz. The protective film 90 is provided so as to cover the OPD layers 30 and is provided so as to cover the upper openings of the first groove 36 (not illustrated in FIG. 9) and the second grooves 37. In also the present embodiment, the protective film 90 is not limited to being a single layer but may be a multilayered film having two or more layers obtained by combining the inorganic insulating film with the organic insulating film (resin film).

With this configuration, in the detection device 1A according to the second embodiment, even if water enters inside the photodiodes PD in the detection region AA from outside, the water is discharged outward (toward the outer edge of the sensor base member 21) through the first groove 36 and the second grooves 37 of the OPD layers 30.

The shapes, the numbers, and the like of the first groove 36 and the second grooves 37 illustrated in FIGS. 8 to 9 are merely exemplary and can be changed as appropriate. For example, the first groove 36 is provided in a continuous frame shape along the outer edge of the detection region AA, but the present disclosure is not limited thereto. A plurality of the first grooves 36 may be provided along each side of the detection region AA. The second grooves 37 are provided in the entire peripheral region GA, but the present disclosure is not limited thereto. Part of the peripheral region GA may be provided with no second grooves 37.

The detection device 1A according to the second embodiment can be combined with the detection device according to the first embodiment described above. That is, in the peripheral region GA, a configuration may be employed in which the OPD layers 30 are provided with the first groove 36 and the second grooves 37, and in the detection region AA, the protective film 90 is provided with the openings OP. In this case, water can be more effectively discharged outward.

### Third Embodiment

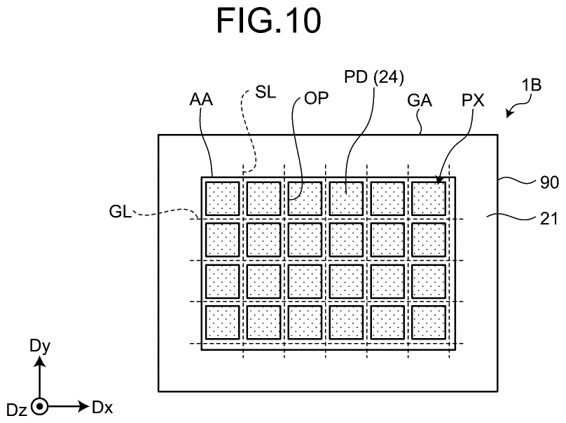

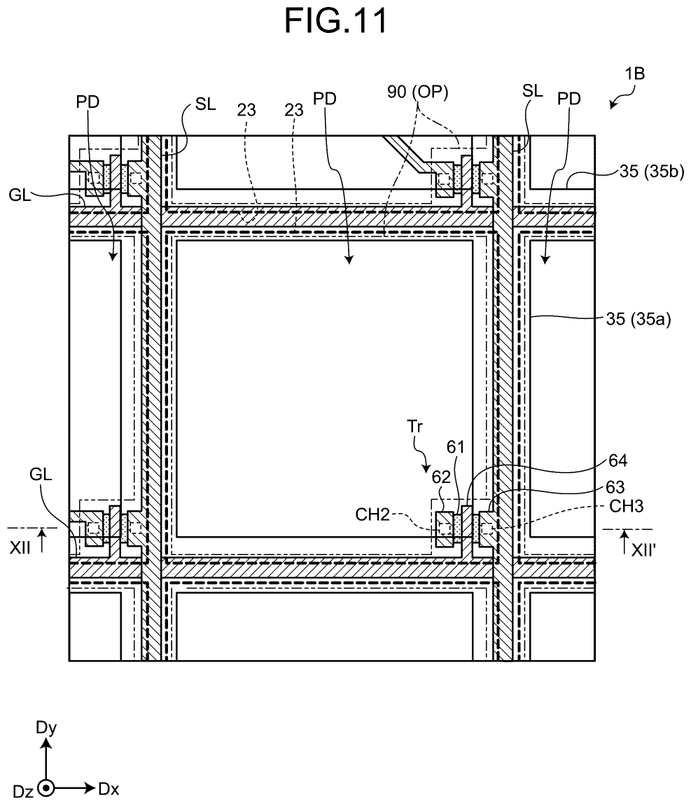

FIG. 10 is a plan view schematically illustrating the pixels and the openings of the protective film of a detection device according to a third embodiment. FIG. 11 is an enlarged schematic configuration diagram of the sensor of the detection device according to the third embodiment.

As illustrated in FIGS. 10 and 11, in a detection device 1B according to the third embodiment, each of the openings OP of the protective film 90 is provided substantially in a quadrilateral shape in the region surrounded by the gate lines GL and signal lines SL. In more detail, as illustrated in FIG. 11, the protective film 90 is provided in a region overlapping the gate lines GL and the signal lines SL and extends along each of the gate lines GL and the signal lines SL. The protective film 90 is provided in a region overlapping the electrodes of the drive transistors Tr. Portions of the protective film 90 that do not overlap the gate lines GL, the signal lines SL, and the electrodes of the drive transistors Tr are removed to form the openings OP.

FIG. 12 is a sectional view along XII-XII′ of FIG. 11. As illustrated in FIG. 12, the circuit forming layer 29 includes an undercoat film 91, a gate insulating film 92, and an interlayer insulating film 93 as insulating films.

The undercoat film 91 has, for example, a two-layered structure that includes insulating films 91a and 91b. The undercoat film 91 is formed of, for example, inorganic insulating films, such as silicon nitride films or silicon oxide films. The configuration of the undercoat film 91 is not limited to that illustrated in FIG. 12. For example, the undercoat film 91 may be a single-layer film or may have three or more layers.

A light-blocking film 67 is provided on the insulating film 91a. The light-blocking film 67 is provided between the semiconductor layer 61 and the sensor base member 21. The light-blocking film 67 can restrain light from entering a channel region of the semiconductor layer 61 from the sensor base member 21 side.

The drive transistor Tr is provided above the sensor base member 21. The semiconductor layer 61 is provided on the undercoat film 91. The gate insulating film 92 is provided on the undercoat film 91 so as to cover the semiconductor layer 61. The gate insulating film 92 is an inorganic insulating film, such as a silicon oxide film. The gate electrode 64 is provided on the gate insulating film 92.

In the example illustrated in FIG. 12, the drive transistor Tr has a top-gate structure. However, the drive transistor Tr is not limited thereto but may have a bottom-gate structure, or a dual-gate structure in which the gate electrodes 64 are provided on the upper side and lower side of the semiconductor layer 61.

The interlayer insulating film 93 is provided on the gate insulating film 92 so as to cover the gate electrode 64. The interlayer insulating film 93 has, for example, a multilayered structure of a silicon nitride film and a silicon oxide film. The source electrode 62 and the drain electrode 63 are provided on the interlayer insulating film 93. The source electrode 62 is coupled to a source region of the semiconductor layer 61 through the contact hole CH2 provided in the gate insulating film 92 and the interlayer insulating film 93. The drain electrode 63 is coupled to a drain region of the semiconductor layer 61 through the contact hole CH3 provided in the gate insulating film 92 and the interlayer insulating film 93.

The insulating film 27 is provided on the interlayer insulating film 93 so as to cover the source electrode 62 and the drain electrode 63 of the drive transistor Tr. In the present embodiment, the contact hole CH1 of the insulating film 27 is provided in a region overlapping the source electrode 62. The lower electrode 23 of the photodiode PD is electrically coupled to the source electrode 62 at the bottom of the contact hole CH1 near the drive transistor Tr.

As illustrated in FIG. 12, the protective film 90 is provided in regions each overlapping a non-light-transmitting pattern of the semiconductor layer 61, the source electrode 62, the drain electrode 63, and the gate electrode 64 of the drive transistor Tr. The openings OP of the protective film 90 are provided in regions each not overlapping the non-light-transmitting pattern of the drive transistor Tr.

In the present embodiment, the area of the openings OP of the protective film 90 in the detection region AA is larger than that in the first embodiment described above, so that water can be more effectively discharged outward.

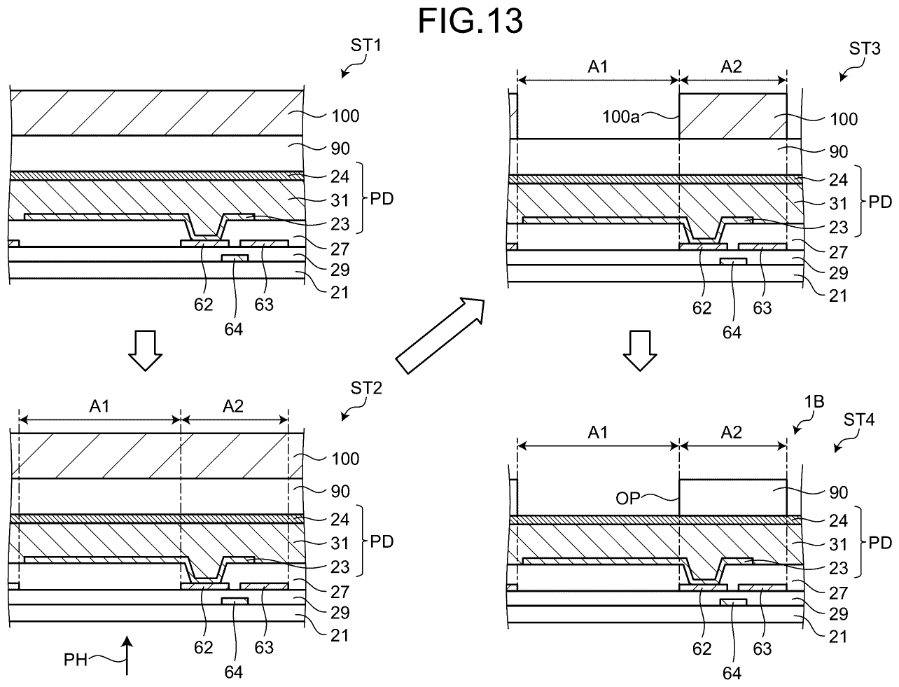

The following describes a method for manufacturing the detection device 1B according to the third embodiment. FIG. 13 is an explanatory diagram for explaining the method for manufacturing the detection device according to the third embodiment. FIG. 13 illustrates a layered configuration of the circuit forming layer 29 and the photodiode PD in a simplified manner for ease of viewing. FIG. 13 illustrates the source electrode 62, the drain electrode 63, and the gate electrode 64 as the non-light-transmitting pattern of the drive transistor Tr included in the circuit forming layer 29, and does not illustrate non-light-transmitting patterns of the gate lines GL, the signal lines SL, and the like.

As illustrated in FIG. 13, in the method for manufacturing the detection device 1B, the circuit forming layer 29, the insulating film 27, the photodiode PD, the protective film 90, and a resist layer 100 are stacked on the sensor base member 21 in the order as listed(Step ST1). Various electrodes, such as the source electrode 62, the drain electrode 63, and the gate electrode 64, and wiring in the circuit forming layer 29 are formed by a sputtering method, a vapor deposition method, a plasma chemical vapor deposition (CVD) method, or another method.

Then, exposure equipment (not illustrated) emits light PH from the lower side of the sensor base member 21. Through this operation, the exposure equipment exposes the resist layer 100 from the lower side of the sensor base member 21 using the non-light-transmitting pattern of the source electrode 62, the drain electrode 63, and the gate electrode 64 as a mask (Step ST2). An exposed region A1 and an unexposed region A2 are formed in the resist layer 100. The exposed region A1 is a region that does not overlap the non-light-transmitting pattern and is irradiated with the light PH. The unexposed region A2 is a region that overlaps the non-light-transmitting pattern and is not exposed to the light PH.

Then, the resist layer 100 is developed and baked (Step ST3). By developing the resist layer 100, the exposed region A1 of the resist layer 100 formed at Step ST2 is removed, and the unexposed region A2 remains. The baking process hardens the unexposed region A2 of the resist layer 100 and forms an opening 100a in a region overlapping the exposed region A1.

The manufacturing equipment then removes a portion of the protective film 90 that does not overlap the resist layer 100, using an etching method (Step ST4). This process forms the opening OP in a region of the protective film 90 that overlaps the exposed region A1, that is, in a region that does not overlap the non-light-transmitting pattern of the circuit forming layer 29. The resist layer 100 is then removed, and the detection device 1B according to the third embodiment is produced.

In the method for manufacturing the detection device 1B according to the third embodiment, the opening OP of the protective film 90 is formed using the non-light-transmitting pattern of the source electrode 62, the drain electrode 63, and the gate electrode 64 as the mask. Therefore, a mask for forming the opening OP need not be prepared, and the opening OP is positioned by what is called self-alignment. This method can simplify the manufacturing process of the detection device 1B. The method for manufacturing illustrated in FIG. 13 is only exemplary and can be changed as appropriate.

### Fourth Embodiment

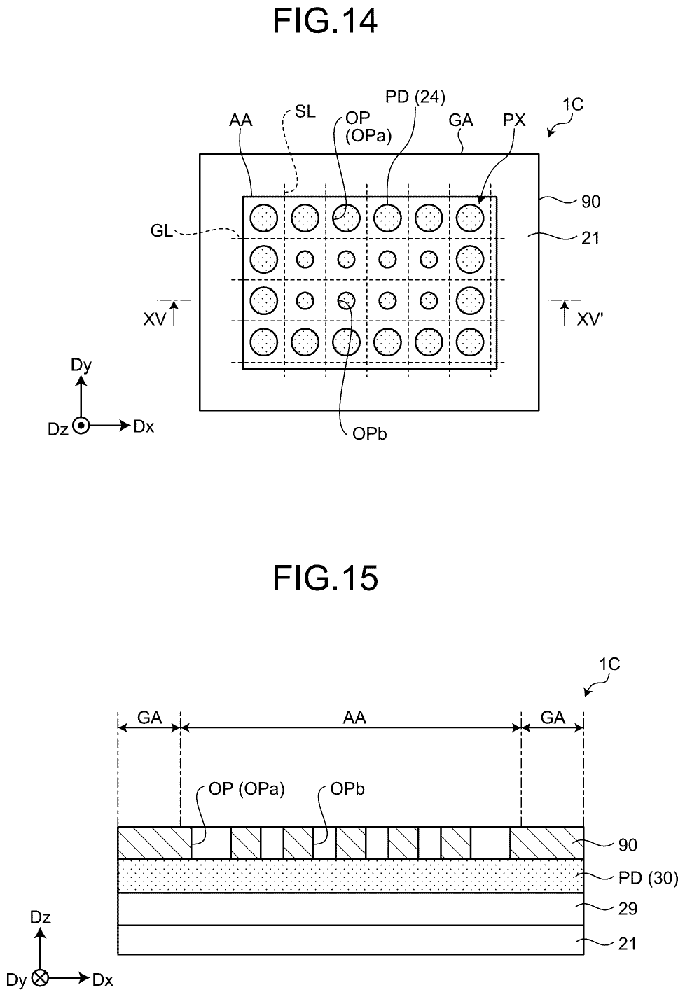

FIG. 14 is a plan view schematically illustrating the pixels and the openings of the protective film of a detection device according to a fourth embodiment. FIG. 15 is a sectional view along XV-XV′ of FIG. 14. As illustrated in FIGS. 14 and 15, in a detection device 1C according to the fourth embodiment, the openings OP provided in the protective film 90 include a plurality of openings OPa located at an outer edge portion of the detection region AA and a plurality of openings OPb located at a central portion of the detection region AA. The area of each of the openings OPb at the central portion of the detection region AA is smaller than that of each of the openings OPa at the outer edge portion of the detection region AA.

In other words, the diameter of each of the openings OPb at the central portion of the detection region AA is smaller than that of each of the openings OPa at the outer edge portion of the detection region AA.

In the detection device 1C according to the fourth embodiment, for example, water that has entered from the outer edge side of the sensor base member 21 is discharged outward through the openings OPa having a relatively larger area at the outer edge portion of the detection region AA. Therefore, in the fourth embodiment, the water that has entered from the outer edge side is discharged at the outer edge portion of the detection region AA.

FIGS. 14 and 15 illustrate the two types of openings OPa and OPb as the openings OP having different areas (sizes). The openings OP are, however, not limited thereto, but may include three or more types of openings having different areas (sizes). In this case, the openings OP are preferably arranged such that the closer the position of the opening OP is from the outer edge portion of the detection region AA to the central portion, the smaller the area is.

### Fifth Embodiment

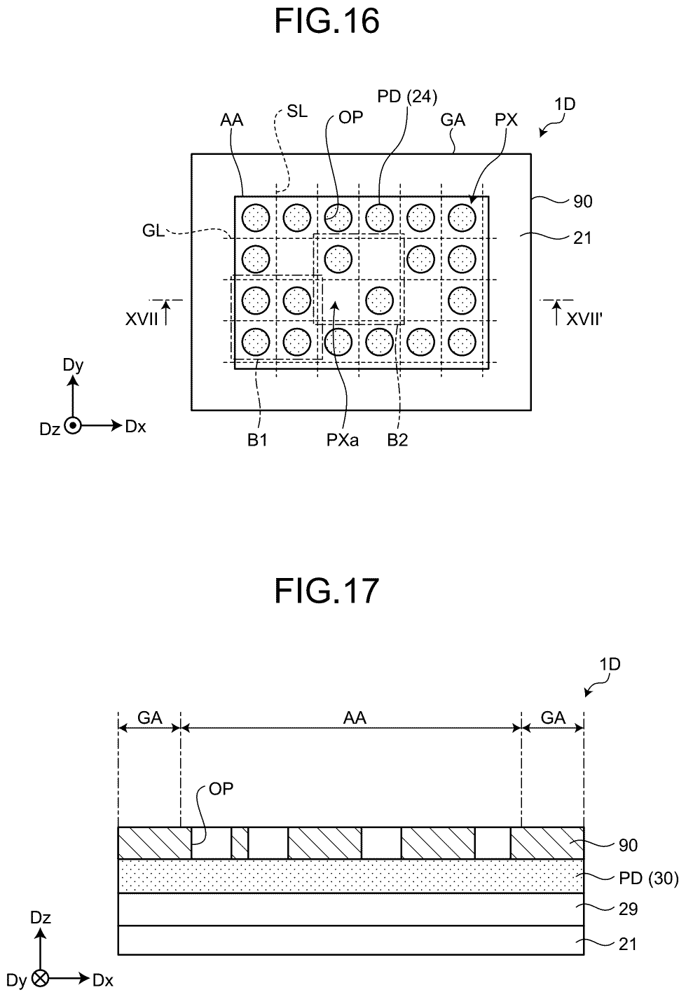

FIG. 16 is a plan view schematically illustrating the pixels and the openings of the protective film of a detection device according to a fifth embodiment. FIG. 17 is a sectional view along XVII-XVII′ of FIG. 16. As illustrated in FIGS. 16 and 17, in a detection device 1D according to the fifth embodiment, the number per predetermined area (arrangement density) of the openings OP decreases towards the center (for example, the centroid) of the detection region AA.

In other words, among the openings OP arranged in a matrix having a row-column configuration in the protective film 90, some of the openings OP at the central portion of the detection region AA are not formed and the other openings OP are formed. Among the sensor pixels PX arranged in a matrix, the sensor pixels PX (for example, a sensor pixel PXa in FIG. 16) for which the openings OP are not provided in the protective film 90 are present at the central portion of the detection region AA.

Specifically, a region including a total of four sensor pixels PX in two rows and two columns is assumed to have a predetermined area. A region B1 located at the outer edge portion of the detection region AA has four of the openings OP. A region B2 located at the central portion of the detection region AA has two of the openings OP.

In the detection device 1D according to the fifth embodiment, for example, water that has entered from the outer edge side of the sensor base member 21 is discharged outward through a relatively larger number of the openings OP (arranged at a relatively larger density) at the outer edge portion of the detection region AA. Therefore, in the fifth embodiment, the water that has entered from the outer edge side is discharged at the outer edge portion of the detection region AA.

The detection device 1D according to the fifth embodiment can be combined with the detection device according to the fourth embodiment described above. That is, the openings OP may be formed in such a way that the number per predetermined area (arrangement density) of the openings OP decreases towards the center of the detection region AA, and the area of the opening OP decreases towards the center of the detection region AA.

### Sixth Embodiment

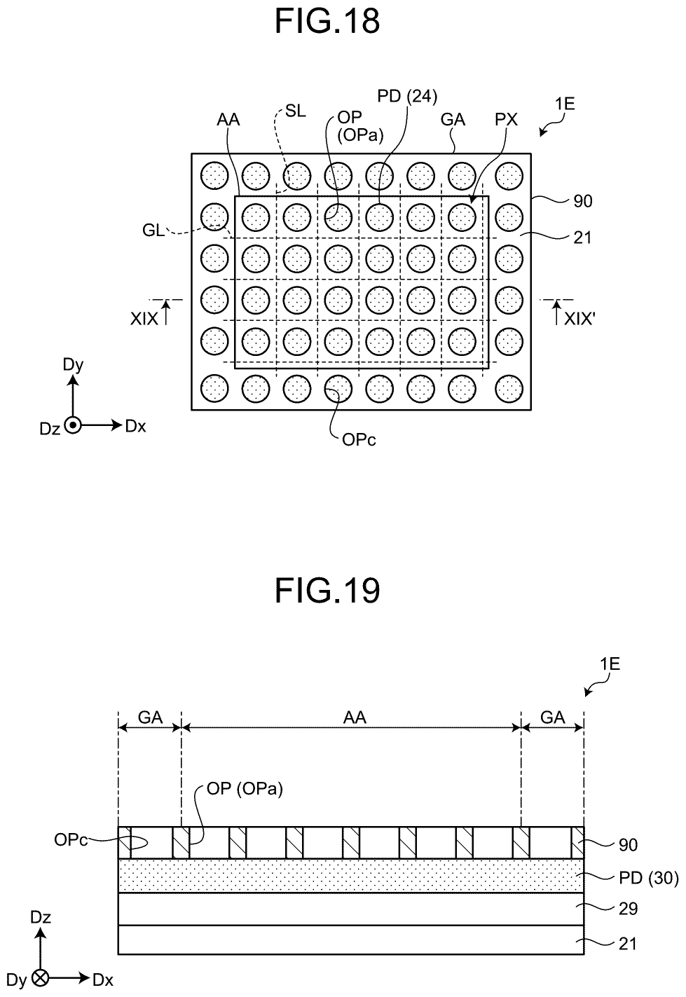

FIG. 18 is a plan view schematically illustrating the pixels and the openings of the protective film of a detection device according to a sixth embodiment. FIG. 19 is a sectional view along XIX-XIX′ of FIG. 18. As illustrated in FIGS. 18 and 19, in a detection device 1E according to the sixth embodiment, the openings OP provided in the protective film 90 include the openings OPa arranged in a matrix having a row-column configuration in the detection region AA and openings OPc provided in the peripheral region GA.

As illustrated in FIG. 18, the openings OPc provided in the peripheral region GA are arranged along each side of the peripheral region GA. The openings OPc provided in the peripheral region GA have the same area (size) or diameter as that of the openings OPa provided in the detection region AA.

In the detection device 1E according to the sixth embodiment, for example, water that has entered from the outer edge side of the sensor base member 21 is discharged outward through the openings OPc provided in the peripheral region GA. Therefore, in the sixth embodiment, the water that has entered from the outer edge side can be restrained from staying in the detection region AA.

The detection device 1E according to the sixth embodiment can be combined with at least one of the detection devices according to the fourth and the fifth embodiments described above. For example, in the detection device 1E, the openings OPa provided in the detection region AA may have a smaller area than that of the openings OPc provided in the peripheral region GA. Alternatively, the number per predetermined area (arrangement density) of the openings OPa provided in the detection region AA may be smaller than the number per predetermined area (arrangement density) of the openings OPc provided in the peripheral region GA.

While the preferred embodiments of the present disclosure have been described above, the present disclosure is not limited to the embodiments described above. The content disclosed in the embodiments is merely an example, and can be variously modified within the scope not departing from the gist of the present disclosure. Any modifications appropriately made within the scope not departing from the gist of the present disclosure also naturally belong to the technical scope of the present disclosure. At least one of various omissions, substitutions, and changes of the components can be made without departing from the gist of the embodiments and the modifications described above.

What is claimed is:

1. A detection device comprising:
a substrate;
a plurality of photodiodes, in each of which a lower electrode, a lower buffer layer, an active layer, an upper buffer layer, and an upper electrode are stacked in the order as listed, in a detection region of the substrate; and
a protective film that covers the photodiodes, wherein
the protective film has a plurality of openings in the detection region.

2. The detection device according to claim 1, further comprising a plurality of sensor pixels that are arranged in a matrix having a row-column configuration in the detection region and have the respective photodiodes, wherein
the openings are provided in regions overlapping the respective sensor pixels and are arranged in a matrix having a row-column configuration in the detection region.

3. The detection device according to claim 1, wherein areas of the openings are substantially equal.

4. The detection device according to claim 1, wherein a number per predetermined area of the openings decreases towards a center of the detection region.

5. The detection device according to claim 1, wherein an area of each of the openings at a central portion of the detection region is smaller than that of each of the openings at an outer edge portion of the detection region.

6. The detection device according to claim 1, wherein each of the openings overlaps the lower buffer layer.

7. The detection device according to claim 1, wherein each of the openings is provided in a region surrounded by gate lines and signal lines.

8. The detection device according to claim 1, wherein the protective film comprises an inorganic insulating film and an organic insulating film.

9. A detection device comprising:
a substrate;
a plurality of photodiodes, in each of which a lower electrode, a lower buffer layer, an active layer, an upper buffer layer, and an upper electrode are stacked in the order as listed, in a detection region of the substrate; and
a protective film that covers the photodiodes, wherein
an organic photodiode (OPD) layer in which the lower electrode, the lower buffer layer, the active layer, the upper buffer layer, and the upper electrode are stacked is provided in the detection region of the substrate and a peripheral region adjacent to the detection region, and
the OPD layer includes a first groove that extends along an outer edge of the detection region and a second groove that is provided between the first groove and an outer edge of the peripheral region.

10. The detection device according to claim 9, wherein the protective film comprises an inorganic insulating film and an organic insulating film.

11. A method for manufacturing a detection device, the method comprising:
stacking a circuit forming layer, a photodiode, a protective film, and a resist layer on one surface of a substrate in the order as listed;
exposing the resist layer from another surface side opposite to the one surface of the substrate using a non-light-transmitting pattern included in the circuit forming layer as a mask; and
removing an exposed region of the resist layer that does not overlap the non-light-transmitting pattern by developing the resist layer, and removing a portion of the protective film that does not overlap the resist layer.
